(19) United States
(12) Patent Application Publication
(10) Pub. No.: US 2007/0029617 A1
(43) Pub. Date: Feb. 8, 2007

(54) Semiconductor device and manufacturing method thereof

(75) Inventor: Juri Kato, Nagano-Ken (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/484,292

(22) Filed: Jul. 10, 2006

(30) Foreign Application Priority Data
Mar. 9, 2006 (JP) 2006-064595
Jul. 8, 2005 (JP) 2005-200026

(51) Int. Cl. H01L 29/76

(52) U.S. Cl. 257/367

(57) ABSTRACT

A semiconductor device includes: a semiconductor layer provided with a P-channel field-effect transistor and an N-channel field-effect transistor that have a common gate electrode, a field plate provided to a back surface of the semiconductor layer with a first insulating layer therebetween and commonly for a channel of the P-channel field-effect transistor and a channel of the N-channel field-effect transistor, and a second insulating layer placed under the field plate.

### BACKGROUND

1. Technical Field

The present invention relates to a semiconductor device and a manufacturing method thereof, and in particular to a method suitable for providing a field plate to field-effect transistors of different conductivity types placed on an insulator.

2. Related Art

Methods have been developed to provide a field plate on an insulating film covering a field-effect transistor in a related art semiconductor device and couple the field plate to the transistor's gate or source, thereby increasing the breakdown voltage of the transistor. JP-A-9-45909 and JP-A-9-205211 are examples of related art.

The related-art field plate structure includes a field plate on an insulating film covering a field-effect transistor. It is therefore necessary to keep the field plate away from the transistor's gate electrode and source/drain contact regions, possibly causing a decrease in the breakdown voltage of the transistor due to electric field concentration at the edges of the gate and the field plate.

As for a silicon-on-insulator (SOI) transistor, when the surface of its Si thin film receives a drain potential, a high voltage is applied to an interface between an offset layer or a heavily-doped impurity diffusion layer in the transistor's drain and a buried oxide layer. Accordingly, a strong electric field occurs locally in the interface, preventing an increase in the breakdown voltage of the transistor.

Furthermore, if the field plate is separated for each field-effect transistor to couple the field plate to the gate or source, a contact region coupled to the field plate needs to be provided for each transistor, which increases the chip size.

In addition, rise characteristics of drain current in the subthreshold region deteriorate as the size of the semiconductor integrated circuit and thus the channel length reduce. This deterioration prevents low-voltage operations of the transistor, increases leakage current during off, requires higher operational and standby power consumption, and causes breakdown of the transistor.

### SUMMARY

An advantage of the invention is to provide a semiconductor device and a manufacturing method thereof that are capable of providing a field plate under field-effect transistors of different conductivity types placed on an insulator while preventing an increase in the chip size.

A semiconductor device according to a first aspect of the invention includes a semiconductor layer provided with a P-channel field-effect transistor and an N-channel field-effect transistor that have a common gate electrode, a field plate provided to a back surface of the semiconductor layer with a first insulating layer therebetween and commonly for a channel of the P-channel field-effect transistor and a channel of the N-channel field-effect transistor, and a second insulating layer placed under the field plate.

This structure enables one field plate to control the potential of active regions in the P- and N-channel field-effect transistors without restricting the layout of the gate electrode and source/drain contact regions. The structure thus can improve rise characteristics of drain current in the subthreshold region and relax an electric field at a drain-side channel edge while preventing a manufacturing process from becoming complicated. Accordingly, the structure can decrease leakage current during off, reduce operational and standby power consumption, and increase the breakdown voltage of the transistors while providing low-voltage transistor operations.

The semiconductor device according to the first aspect may also include a wiring layer that couples the gate electrode and the field plate.

With the single coupling point on the field plate, it is possible to control the back sides of the channel regions of the P- and N-channel field-effect transistors to have the same potential as the gate electrode, which increases control over the potential of deep channel regions. Accordingly, this structure can decrease leakage current during off, reduce operational and standby power consumption, and increase the breakdown voltage of the transistors while preventing an increase in the chip size.

In the semiconductor device according to the first aspect, the field plate may have an area larger than active regions in the P- and N-channel field-effect transistors.

This structure can make the contact regions in the field plate away from the active regions, prevent a manufacturing process from becoming complicated, and control the gate electrode and the field plate to have the same potential.

In the semiconductor device according to the first aspect, the field plate may be thicker than the semiconductor layer.

This structure allows the field plate to have low resistance by adjusting its thickness. Even if the field plate has a large area, it is possible to stabilize its potential while preventing a manufacturing process from becoming complicated.

In the semiconductor device according to the first aspect, the semiconductor layer and the field plate may be made of one of single crystal, polycrystalline, and amorphous semiconductor materials.

It is therefore possible to provide the field plate under the P- and N-channel field-effect transistors stably by depositing the semiconductor layer.

In the semiconductor device according to the first aspect, the first insulating layer may be thicker than a gate insulating film included in the P- and N-channel field-effect transistors.

This structure can reduce the parasitic capacitance of the source/drain layer relative to the field plate.

In the semiconductor device according to the first aspect, the second insulating layer may be thicker than the first insulating layer.

This structure can reduce the parasitic capacitance of the field plate formed through the second insulating layer. Even if the gate electrode is coupled to the field plate, it is possible to prevent the driving performance of the gate electrode from lowering and increase control over the potential of the channel regions in the width direction. Accordingly, the threshold voltages of the transistors can be easily controlled.

Furthermore, since the first insulating layer is thinner, the field plate can increase control over the potential of the channel regions regardless of whether the field plate is connected to the gate electrode or not. Accordingly, the threshold values of the transistors can be easily controlled. In addition, the driving performance of the transistors can be enhanced.

A semiconductor device according to a second aspect of the invention includes a semiconductor layer to be mesa-isolated on a first insulating layer, an isolation insulating layer buried between one region and another region of the mesa-isolated semiconductor layer, a P-channel field-effect transistor and an N-channel field-effect transistor provided to the semiconductor layer so as to have a common gate electrode crossing the isolation insulating layer, a field plate provided to a back surface of the semiconductor layer with the first insulating layer therebetween and commonly for a channel of the P-channel field-effect transistor and a channel of the N-channel field-effect transistor, a second insulating layer placed under the field plate, and a buried electrode penetrating the gate electrode, the isolation insulating layer, and the first insulating layer so as to be coupled to the semiconductor layer.

The P- and N-channel field-effect transistors can thus be isolated on the first insulating layer. Moreover, with the single coupling point on the field plate to the gate electrode through the isolation insulating layer, it is possible to control the back sides of the transistors' channel regions to have the same potential as the gate electrode. Accordingly, this structure can decrease leakage current during off, reduce operational and standby power consumption, and increase the breakdown voltage of the transistors while preventing an increase in the chip size.

A method for manufacturing a semiconductor device according to a third aspect of the invention includes: providing a first semiconductor layer on a first insulating layer and providing a second semiconductor layer on the first semiconductor layer with a second insulating layer therebetween, patterning the second semiconductor layer to mesa-isolate the second semiconductor layer into a first region and a second region, burying an isolation insulating layer between one region and another region of the mesa-isolated second insulating layer, providing a gate insulating film on a surface of the first region and a surface of the second region of the second semiconductor layer, providing a gate electrode on the gate insulating film to cross the isolation insulating layer and cover the first region and the second region of the second semiconductor layer, providing a first-conductivity-type source/drain layer in the first region of the second semiconductor layer, providing a second-conductivity-type source/drain layer in the second region of the second semiconductor layer, and providing a buried electrode penetrating the gate electrode, the isolation insulating layer, and the second insulating layer so as to be coupled to the first semiconductor layer.

This method allows the first semiconductor layer to function as a field plate, SOI transistors to be provided to the second semiconductor layer, and the field plate to be provided to the back surface of the second semiconductor layer provided with the SOI transistors. With the single contact point on the field plate, it is possible to couple the gate electrode of both the P- and N-channel field-effect transistors and the field plate. Accordingly, the method can place the field plate in a region of electric field concentration without restricting the layout of the gate electrode and source/drain contact regions. The method can thus reduce leakage current during off and increase the breakdown voltage of a complementary metal-oxide semiconductor (CMOS) circuit while preventing an increase in the chip size.

A method for manufacturing a semiconductor device according to a fourth aspect of the invention includes: providing a plurality of multilayer structures on a semiconductor substrate, each multilayer structure including a first semiconductor layer and a second semiconductor layer whose etching rate is smaller than an etching rate of the first semiconductor layer on the first semiconductor layer, providing a first trench penetrating the first semiconductor layer and the second semiconductor layer to expose the semiconductor substrate and providing a second trench penetrating an upper first semiconductor layer and an upper second semiconductor layer to expose a lower second semiconductor layer, providing a support member buried in the first trench and the second trench to support the second semiconductor layer on the semiconductor substrate, providing an exposing part to expose at least part of the first semiconductor layer from the second semiconductor layer, selectively etching the first semiconductor layer through the exposing part to form a cavity from which the first semiconductor layer is removed, providing a buried insulating layer buried in the cavity, making the support member thin to provide an isolation insulating layer buried in the first trench, providing a gate insulating film on a surface of the first region and a surface of the second region of the second semiconductor layer isolated by the first trench, providing a gate electrode on the gate insulating film to cross the isolation insulating layer and cover the first region and the second region of the second semiconductor layer, providing a first-conductivity-type source/drain layer in the first region of the second semiconductor layer, and providing a second-conductivity-type source/drain layer in the second region of the second semiconductor layer.

This method allows the first semiconductor layer to function as a field plate without using an SOI substrate, SOI transistors to be provided to the second semiconductor layer, and the field plate to be provided to the back surface of the second semiconductor layer provided with the SOI transistors. Even if the second semiconductor layer is deposited on the first semiconductor layer, it is possible to bring the first semiconductor layer into contact with an etching gas or fluid through the exposing part. It is therefore possible to remove the first semiconductor layer with the second semiconductor layer remaining unremoved by means of a difference in selectivity between the first and second semiconductor layers, and to provide the buried insulating layer buried in the cavity under the second semiconductor layer. Furthermore, even if the cavity is provided under the second semiconductor layer, it is possible to support the second semiconductor layer on the semiconductor substrate by providing the support member buried in the first and second trenches, and provide a shallow trench isolation (STI) structure.

Consequently, the method can provide the second semiconductor layer on the buried insulating layer while reducing defect occurrences of the second semiconductor layer, and isolate the second semiconductor layer placed on the field plate while preventing a manufacturing process from becoming complicated. The method thus can prevent manufacturing costs from increasing, reduce leakage current of a CMOS circuit during off, and increase the breakdown voltage of the CMOS circuit.

### BRIEF DESCRIPTION OF THE DRAWINGS

The invention will be described with reference to the accompanying drawings, wherein like numbers reference like elements.

FIG. 1 is a perspective view schematically showing a semiconductor device according to a first embodiment of the invention.

FIG. 2 shows an example circuit included in the semiconductor device shown in FIG. 1.

FIGS. 3A to 3C show a method for manufacturing a semiconductor device according to a second embodiment of the invention.

FIGS. 4A to 4C show the method for manufacturing a semiconductor device according to the second embodiment.

FIGS. 5A to 5C show the method for manufacturing a semiconductor device according to the second embodiment.

FIGS. 6A to 6C show the method for manufacturing a semiconductor device according to the second embodiment.

FIGS. 7A to 7C show the method for manufacturing a semiconductor device according to the second embodiment.

FIGS. 8A to 8C show the method for manufacturing a semiconductor device according to the second embodiment.

FIGS. 9A to 9C show the method for manufacturing a semiconductor device according to the second embodiment.

FIGS. 10A to 10C show the method for manufacturing a semiconductor device according to the second embodiment.

FIGS. 11A to 11C show the method for manufacturing a semiconductor device according to the second embodiment.

FIGS. 12A to 12C show the method for manufacturing a semiconductor device according to the second embodiment.

### DESCRIPTION OF EXEMPLARY EMBODIMENTS

A semiconductor device and a manufacturing method thereof according to embodiments of the invention will now be described with reference to the accompanying drawings.

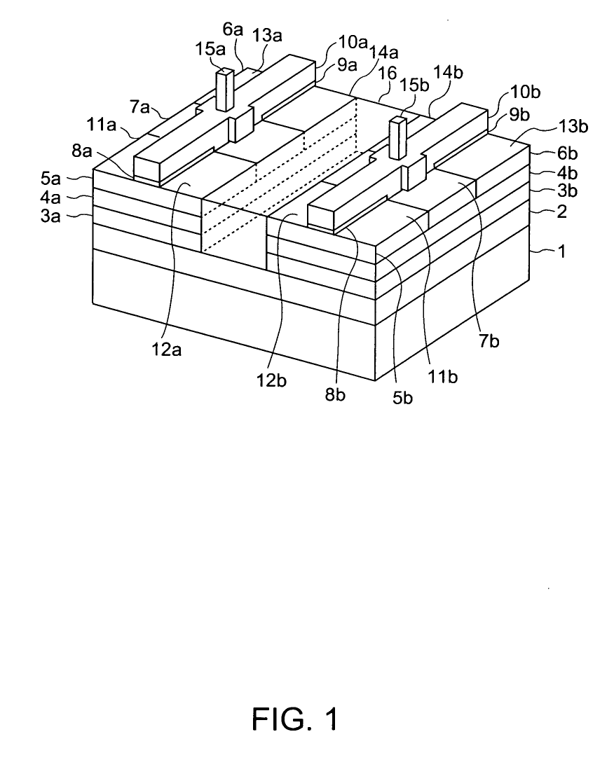

FIG. 1 is a perspective view schematically showing a semiconductor device according to a first embodiment of the invention.

Referring to FIG. 1, an insulating layer 2 is provided on a semiconductor substrate 1, and mesa-isolated single crystal semiconductor layers 3a and 3b are provided on the insulating layer 2. Provided on the semiconductor layer 3a with an insulating layer 4a therebetween are mesa-isolated single crystal semiconductor layers 5a and 6a. Provided on the semiconductor layer 3b with an insulating layer 4b therebetween are mesa-isolated single crystal semiconductor layers 5b and 6b. The semiconductor substrate 1 and the semiconductor layers 3a, 3b, 5a, 6a, 5b, and 6b may be made of Si, Ge, SiGe, GaAs, InP, GaP, GaN, or SiC, for example. Instead of the semiconductor layers 3a, 3b, 5a, 6a, 5b, and 6b, polycrystalline or amorphous semiconductor layers may be used.

Between the mesa-isolated single crystal semiconductor layers 5a and 6a, an isolation insulating layer 7a is buried. Between the mesa-isolated single crystal semiconductor layers 5b and 6b, an isolation insulating layer 7b is buried. The isolation insulating layer 7b is also buried between the mesa-isolated single crystal semiconductor layers 3a and 3b.

Provided on the single crystal semiconductor layers 5a and 6a with gate insulating films 8a and 9a, respectively, therebetween is a gate electrode 10a crossing the isolation insulating layer 7a. Sandwiching the gate electrode 10a, a P-type source layer 11a and a P-type drain layer 12a are provided to the semiconductor layer 5a. Also sandwiching the gate electrode 10a, an N-type source layer 13a and an N-type drain layer 14a are provided to the semiconductor layer 6a. The gate electrode 10a is provided with a buried electrode 15a penetrating the gate electrode 10a, the isolation insulating layer 7a, and the insulating layer 4a to be coupled to the semiconductor layer 3a.

Provided on the single crystal semiconductor layers 5b and 6b with gate insulating films 8b and 9b, respectively, therebetween is a gate electrode 10b crossing the isolation insulating layer 7b. Sandwiching the gate electrode 10b, a P-type source layer 11b and a P-type drain layer 12b are provided to the semiconductor layer 5b. Also sandwiching the gate electrode 10b, an N-type source layer 13b and an N-type drain layer 14b are provided to the semiconductor layer 6b. The gate electrode 10b is provided with a buried electrode 15b penetrating the gate electrode 10b, the isolation insulating layer 7b, and the insulating layer 4b to be coupled to the semiconductor layer 3b.

This structure allows the single crystal semiconductor layers 3a and 3b to function as field plates, an SOI transistor to be provided to the single crystal semiconductor layers 5a, 6a, 5b, and 6b, and the field plates to be provided to the back surfaces of the semiconductor layers 5a, 6a, 5b, and 6b provided with the SOI transistor. With the single contact point on the field plates, it is possible to couple the gate electrodes 10a and 10b of both P- and N-channel field-effect transistors and the field plates. Accordingly, the structure can place the field plates in regions of electric field concentration without restricting the layout of the gate electrodes 10a and 10b and the source/drain contact regions and increase control over potential of deep channel regions. The structure can thus reduce leakage current during off and increase the breakdown voltage of a complementary metal-oxide semiconductor (CMOS) circuit while preventing an increase in the chip size.

It is preferable that the single crystal semiconductor layer 3a have a larger area than the total area of the single crystal semiconductor layers 5a and 6a, and the single crystal semiconductor layer 3b have a larger area than the total area of the single crystal semiconductor layers 5b and 6b. This structure can make contact regions in the field plates away from active regions, prevent a manufacturing process from becoming complicated, and control the gate electrodes and the field plates to have the same potential.

It is preferable that the single crystal semiconductor layer 3a be thicker than the single crystal semiconductor layers 5a, 6a, 5b and 6b. This structure allows the field plates to have low resistance by adjusting the thickness of the semiconductor layer 3a. Even if the field plates have large areas, it is possible to stabilize the potential of the field plates while preventing a manufacturing process from becoming complicated.

It is preferable that the insulating layers 4a and 4b be thicker than the gate insulating films 8a, 9a, 8b, and 9b. This structure can reduce the parasitic capacitance of the P-type source layer 11a, the P-type drain layer 12a, the N-type source layer 13a, and the N-type drain layer 14a relative to the single crystal semiconductor layer 3a and reduce the parasitic capacitance of the P-type source layer 11b, the P-type drain layer 12b, the N-type source layer 13b, and the N-type drain layer 14b relative to the single crystal semiconductor layer 3b. Thus, the on current of the field-effect transistors can be increased.

It is preferable that the insulating layer 2 be thicker than the insulating layers 4a and 4b. This structure can reduce the parasitic capacitance of the single crystal semiconductor layers 3a and 3b formed through the insulating layer 2. Even if the gate electrodes 10a and 10b are coupled to the single crystal semiconductor layer 3a and 3b, respectively, it is possible to prevent the driving performance of the gate electrodes 10a and 10b from lowering and increase control over potential of the single crystal semiconductor layers 5a, 6a, 5b, and 6b in the width direction. Accordingly, threshold voltages can be easily controlled and the rising property of the drain current in the subthreshold region can increase.

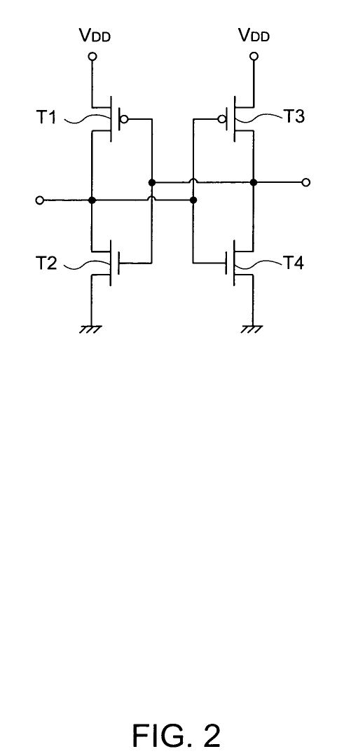

FIG. 2 shows an example circuit included in the semiconductor device shown in FIG. 1.

Referring to FIG. 2, the gate of a P-channel field-effect transistor T1 and the gate of an N-channel field-effect transistor T2 are coupled to each other, while the gate of a P-channel field-effect transistor T3 and the gate of an N-channel field-effect transistor T4 are coupled to each other. The drain of the P-channel field-effect transistor T1 and the drain of the N-channel field-effect transistor T2 are coupled to each other and coupled commonly to the gate of the P-channel field-effect transistor T3 and the gate of the N-channel field-effect transistor T4. The drain of the P-channel field-effect transistor T3 and the drain of the N-channel field-effect transistor T4 are coupled to each other and coupled commonly to the gate of the P-channel field-effect transistor T1 and the gate of the N-channel field-effect transistor T2. The sources of the P-channel field-effect transistors T1 and T3 are coupled to a power supply potential VDD, while the sources of the N-channel field-effect transistors T2 and T4 are grounded.

The P-channel field-effect transistor T1 can be composed of the gate electrode 10a, the P-type source layer 11a, and the P-type drain layer 12a shown in FIG. 1. The N-channel field-effect transistor T2 can be composed of the gate electrode 10a, the N-type source layer 13a, and the N-type drain layer 14a shown in FIG. 1. The P-channel field-effect transistor T3 can be composed of the gate electrode 10b, the P-type source layer 11b, and the P-type drain layer 12b shown in FIG. 1. The N-channel field-effect transistor T4 can be composed of the gate electrode 10b, the N-type source layer 13b, and the N-type drain layer 14b shown in FIG. 1.

This structure makes it possible to provide a field plate commonly to the back surfaces of a P-channel SOI transistor and an N-channel SOI transistor, and also to provide a CMOS inverter or a flip-flop. It is therefore possible to provide an element with various functions while preventing an increase in the chip size, and achieve a CMOS circuit working on low power and voltage with high breakdown voltage.

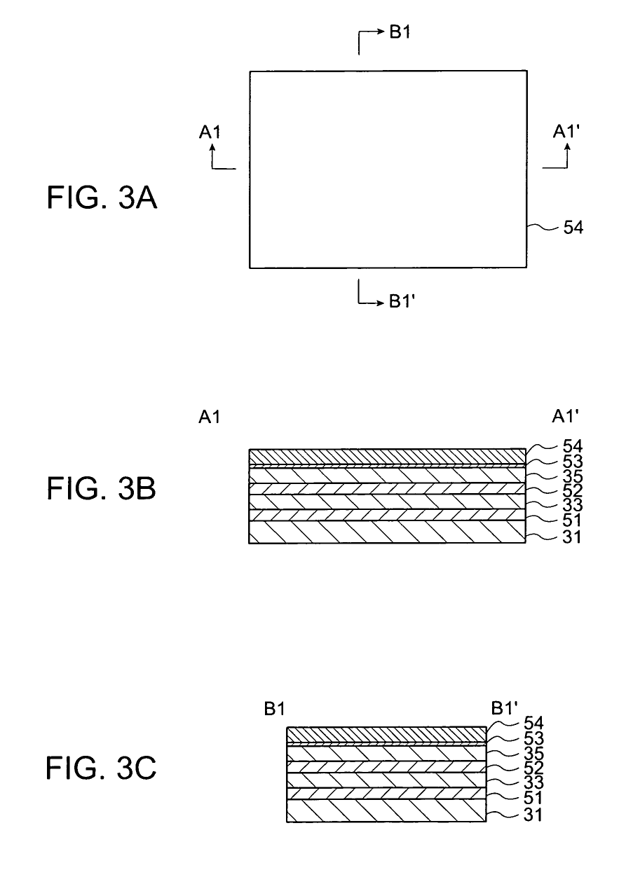

FIGS. 3A to 12A are plane views showing a method for manufacturing a semiconductor device according to a second embodiment of the invention. FIGS. 3B to 12B are sectional views along lines A1-A1′ to A10-A10′ of FIGS. 3A to 12A, respectively. FIGS. 3C to 12C are sectional views along lines B1-B1′ to B10-B10′ of FIGS. 3A to 12A, respectively.

Referring to FIGS. 3A to 3C, single crystal semiconductor layers 51, 33, 52, and 35 are deposited subsequently on a semiconductor substrate 31. The semiconductor layers 51 and 52 can be made of a material having a larger etching rate than the semiconductor substrate 31 and the semiconductor layers 33 and 35. Particularly if the semiconductor substrate 31 is made of Si, it is preferable that the semiconductor layers 51 and 52 be made of SiGe, while the semiconductor layers 33 and 35 be made of Si. Accordingly, it is possible to achieve lattice matching between the semiconductor layers 51 and 52 and the semiconductor layers 33 and 35 and also to ensure selectivity between the semiconductor layers 51 and 52 and the semiconductor layers 33 and 35. Instead of the semiconductor layers 51, 33, 52, and 35, polycrystalline, amorphous, or porous semiconductor layers may be used. The semiconductor layers 51 and 52 may be replaced with gamma-aluminum oxide or other metal oxide films on which a single crystal semiconductor layer can be deposited by epitaxial growth. The semiconductor layers 51, 33, 52, and 35 can be provided to a thickness of about 1 to 100 nm, for example.

By thermal oxidation or chemical vapor deposition (CVD) of the single crystal semiconductor layer 35, a sacrifice oxide film 53 is formed on its surface. Then by CVD, for example, an anti-oxidation film 54 is provided to the whole surface of the sacrifice oxide film 53. As the anti-oxidation film 54, a silicon nitride film may be used, for example.

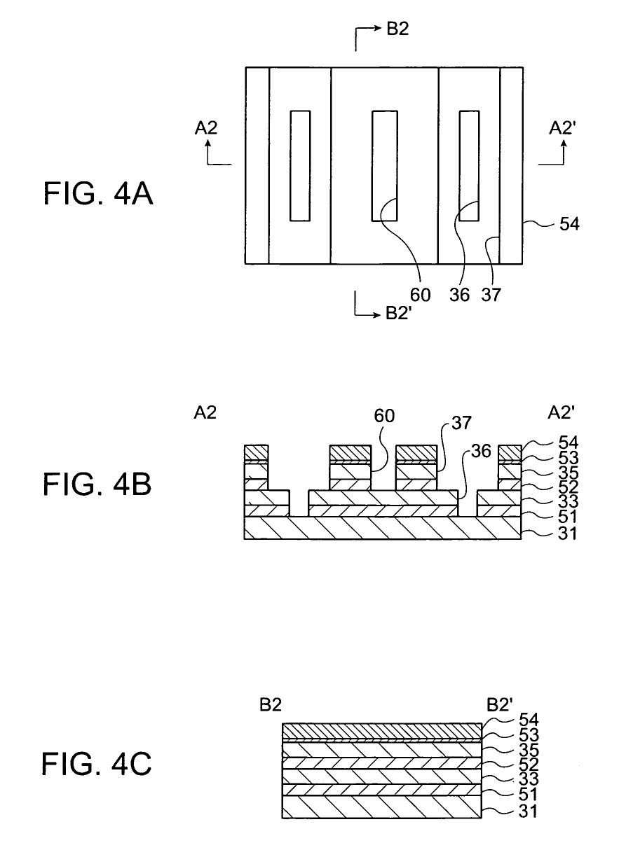

Referring now to FIGS. 4A to 4C, the anti-oxidation film 54, the sacrifice oxide film 53, and the single crystal semiconductor layers 35, 52, 33, and 51 are patterned by photolithography and etching to form a trench 36 to expose the semiconductor substrate 31 in a predetermined direction. To expose the substrate 31, etching may be performed until reaching the surface of the substrate 31, or the substrate 31 may be overetched to form a concave thereon. The trench 36 may be provided corresponding to part of the isolation region of the semiconductor layer 33.

The anti-oxidation film 54, the sacrifice oxide film 53, and the single crystal semiconductor layers 35 and 52 are further patterned by photolithography and etching to form a second trench 37 that is wider than the first trench 36 and superposed on the first trench 36 and also to form a third trench 60 inside the semiconductor layer 35 to expose the surface of the single crystal semiconductor layer 33. The second and third trenches 37 and 60 may be provided corresponding to the isolation region of the semiconductor layer 35.

Instead of exposing the surface of the single crystal semiconductor layer 33, etching may be performed until reaching the surface of the single crystal semiconductor layer 52. Otherwise, the semiconductor layer 52 may be overetched until etching reaches a certain point therein. It is therefore possible to prevent the surface of the semiconductor layer 33 in the trenches 36 and 60 from being exposed. This structure can reduce time for exposing the semiconductor layer 33 in the trenches 36 and 60 to an etching fluid or gas that etches and removes the semiconductor layers 51 and 52, preventing overetching of the semiconductor layer 33 in the trenches 36 and 60.

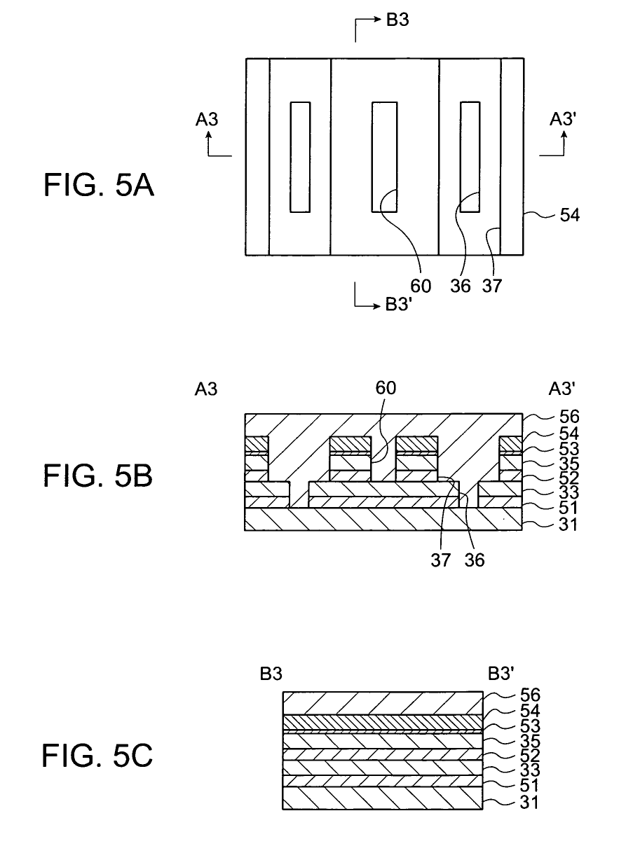

Referring now to FIGS. 5A to 5C, a support member 56 buried in the trenches 36, 37, and 60 to support the single crystal semiconductor layers 33 and 35 on the semiconductor substrate 31 is provided on the whole surface of the substrate 31 by CVD, for example. The support member 56 may be made of an insulator, such as a silicon oxide or nitride film, for example.

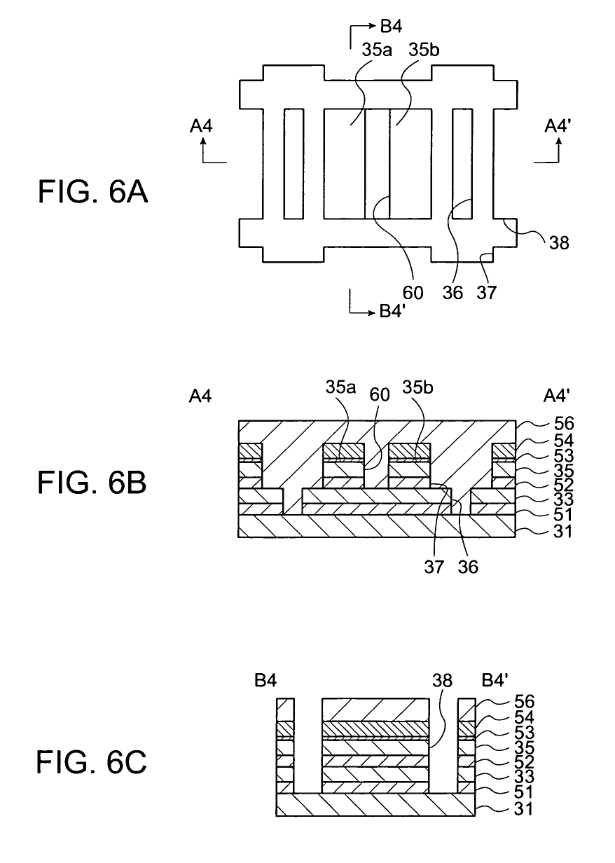

Referring now to FIGS. 6A to 6C, the anti-oxidation film 54, the sacrifice oxide film 53, and the single crystal semiconductor layers 35, 52, 33, and 51 are further patterned by photolithography and etching to form a fourth trench 38 to expose the semiconductor substrate 31 in the direction perpendicular to the first trench 36. The fourth trench 38 may be provided such that the third trench 60 divides the semiconductor layer 35 into single crystal semiconductor layers 35a and 35b. To expose the semiconductor substrate 31, etching may be performed until reaching the surface of the substrate 31, or the substrate 31 may be overetched to form a concave thereon. The fourth trench 38 may be provided corresponding to the isolation regions of the semiconductor layers 33 and 35.

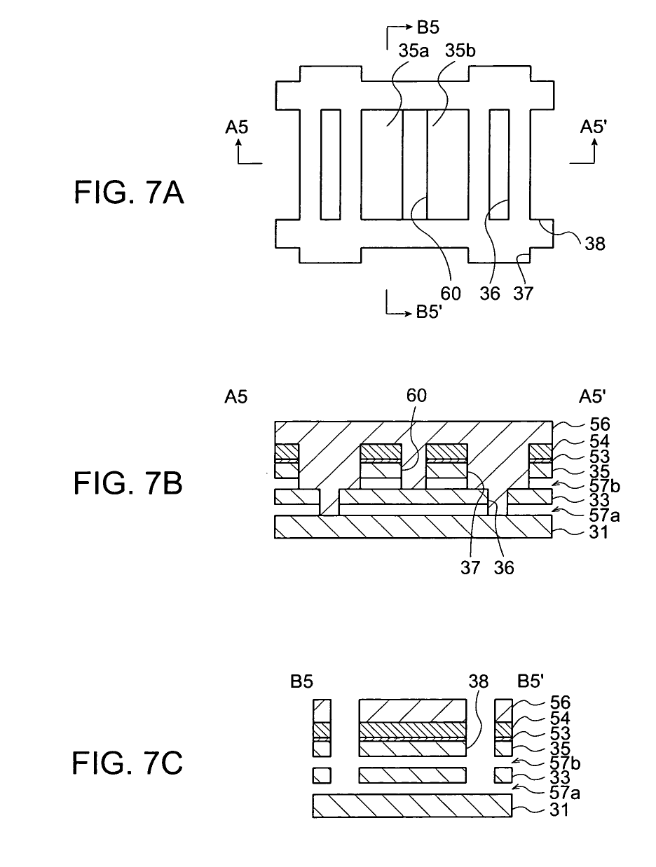

Referring now to FIGS. 7A to 7C, the single crystal semiconductor layers 51 and 52 are etched and removed by contact with an etching gas or fluid through the fourth trench 38. Thus a cavity 57a is formed between the semiconductor substrate 31 and the single crystal semiconductor layer 33, while a cavity 57b is formed between the semiconductor layers 33 and 35.

Since the support member 56 is provided in the first and second trenches 36 and 37, it is possible to support the semiconductor layers 33 and 35 on the semiconductor substrate 31 after the semiconductor layers 51 and 52 are removed. The fourth trench 38 formed in addition to the first and second trenches 36 and 37 makes it possible to bring the semiconductor layers 51 and 52 placed under the semiconductor layers 33 and 35, respectively, into contact with an etching gas or fluid. Accordingly, it is possible to achieve insulation between the semiconductor layers 33 and 35 and the semiconductor substrate 31 without harming the crystal quality of the semiconductor layers 33 and 35.

If the semiconductor substrate 31 and the single crystal semiconductor layers 33 and 35 are made of Si and the single crystal semiconductor layers 51 and 52 are made of SiGe, it is preferable that hydrofluoric-nitric acid (HF, HNO₃, H₂) be used as the etching fluid for the semiconductor layers 51 and 52. The selectivity ratio between Si and SiGe is thus about 1:100 to 1:1000. It is therefore possible to remove the semiconductor layers 51 and 52 while preventing overetching of the semiconductor substrate 31 and the semiconductor layers 33 and 35. As the etching fluid for the semiconductor layers 51 and 52, hydrofluoric-nitric acid hydrogen peroxide, ammonia hydrogen peroxide, or hydrofluoric-acetic acid hydrogen peroxide.

Before being etched and removed, the single crystal semiconductor layers 51 and 52 may be made porous by anodic oxidation, for example, or they may be made amorphous by ion implantation. It is therefore possible to increase etching rates of the semiconductor layers 51 and 52. Accordingly, it is possible to increase etched areas in the semiconductor layers 51 and 52 while preventing overetching of the semiconductor layers 33 and 35.

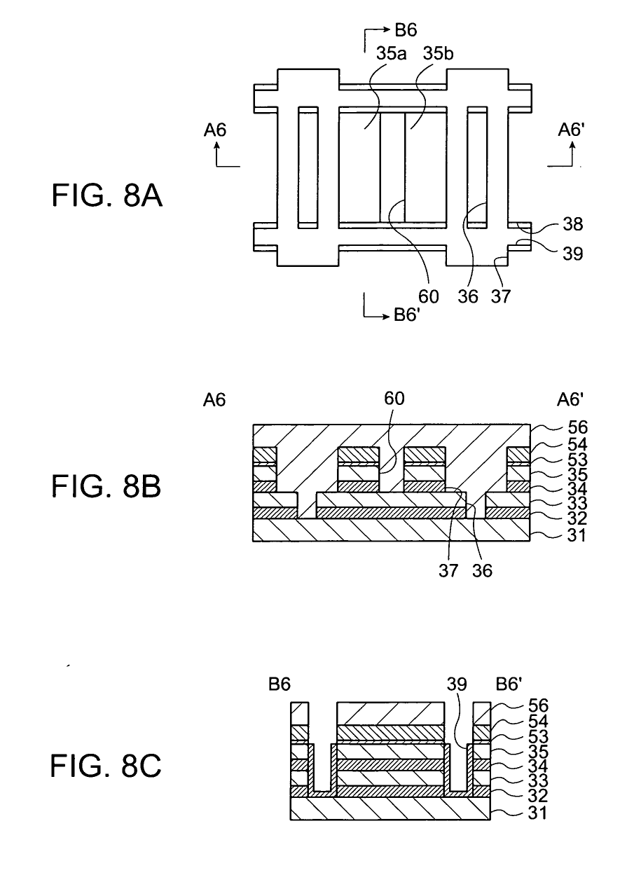

Referring now to FIGS. 8A to 8C, a buried insulating layer 32 is provided in the cavity 57a between the semiconductor substrate 31 and the single crystal semiconductor layer 33 and another buried insulating layer 34 is provided in the cavity 57b between the single crystal semiconductor layers 33 and 35 by thermal oxidation of the substrate 31 and the semiconductor layers 33 and 35. To provide the buried insulating layers 32 and 34 by thermal oxidation of the substrate 31 and the semiconductor layers 33 and 35, it is preferable that low-temperature wet oxidation that provides reaction rate controlling be used to improve embedding properties. By providing the buried insulating layers 32 and 34 by thermal oxidation of the substrate 31 and the semiconductor layers 33 and 35, the substrate 31 and the semiconductor layers 33 and 35 in the fourth trench 38 are oxidized, thereby providing an oxide film 39 to the sidewall inside the trench 38.

Accordingly, the thicknesses of the single crystal semiconductor layers 33 and 35 after epitaxial growth and the thicknesses of the buried insulating layers 32 and 34 provided by the thermal oxidation of the semiconductor layers 33 and 35 define the thicknesses of the semiconductor layers 33 and 35 after isolation. It is therefore possible to precisely control the thicknesses of the semiconductor layers 33 and 35 to reduce variance in their thicknesses and make the semiconductor layers 33 and 35 thin. Furthermore, providing the anti-oxidation film 54 on the semiconductor layer 35 prevents thermal oxidation of the surface of the semiconductor layer 35 and makes it possible to provide the buried insulating layer 34 on the back surface of the semiconductor layer 35.

Here, providing the buried insulating layers 32 and 34 in the cavities 57a and 57b, respectively, may be followed by high-temperature annealing at 1000 degrees centigrade or more. It is therefore possible to reflow the buried insulating layers 32 and 34 to reduce stress on the insulating layers 32 and 34 and also to reduce the interface state at their boundaries with the single crystal semiconductor layers 33 and 35. The insulating layers 32 and 34 may be provided to entirely fill the cavities 57a and 57b or leave part of the cavities 57a and 57b unfilled.

While the method referring to FIGS. 8A to 8C provides the buried insulating layers 32 and 34 in the cavities 57a and 57b between the semiconductor substrate 31 and the single crystal semiconductor layers 33 and 35 by the thermal oxidation of the substrate 31 and the semiconductor layers 33 and 35, the insulating layers 32 and 34 can also be buried in the cavities 57a and 57b by providing insulating films therein by CVD. In this case, it is possible to fill the cavities 57a and 57b between the substrate 31 and the semiconductor layers 33 and 35 with other material than an oxide film, while preventing reduction in the thicknesses of the semiconductor layers 33 and 35. It is therefore possible to increase the thickness of the buried insulating layer 32 between the substrate 31 and the semiconductor layer 33 and reduce a dielectric constant, thereby reducing the parasitic capacitance of the semiconductor layer 33.

Examples of materials of the buried insulating layers 32 and 34 include fluorosilicate glass (FSG) and silicon nitride films as well as a silicon oxide film. Otherwise, the buried insulating layers 32 and 34 may be made of phosphorous-doped glass (PSG), boron-phosphorous-doped glass (BPSG), polyarylene ether (PAE), hydrogen silsesquioxane (HSQ), methyl silsesquioxane (MSQ), polychlorinated biphenyl (PCB), carbon fluoride (CF), SiOC, SiOF, and other organic low-k films, and their porous films as well as a spin-on glass (SOG) film.

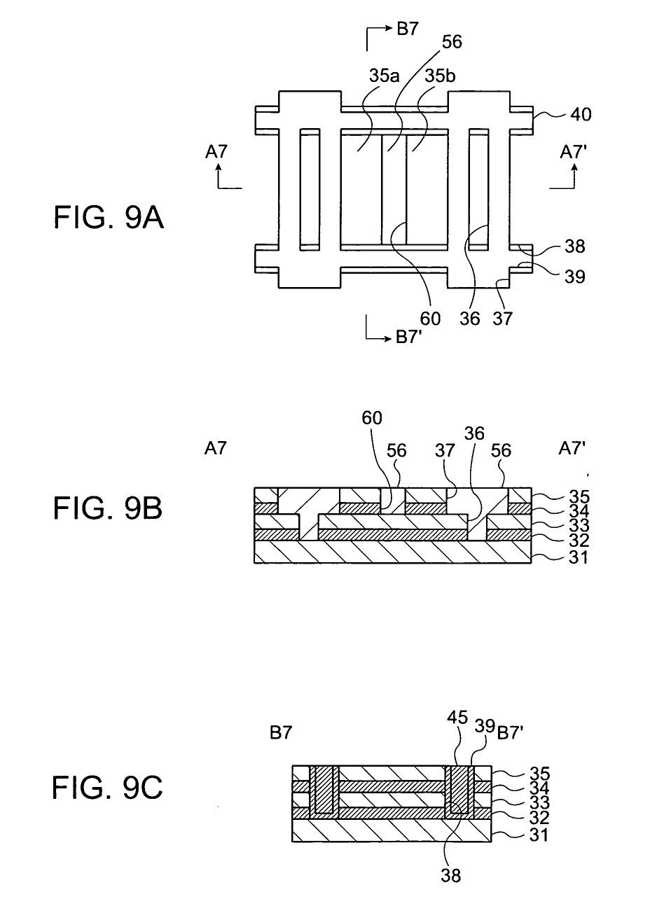

Referring next to FIGS. 9A to 9C, an insulating layer 45 is deposited on the support member 56 to fill the fourth trench 38 by CVD, for example. Then chemical mechanical polishing (CMP), for example, is conducted to make the insulating layer 45 and the support member 56 thin and remove the anti-oxidation film 54 and sacrifice oxide film 53, thereby exposing the surface of the single crystal semiconductor layer 35. As the insulating layer 45, SiO₂ or Si₃N₄ may be used, for example.

Here, III or IV group element ions are injected into the single crystal semiconductor layer 33 with an appropriate acceleration energy to achieve electrical activation by annealing.

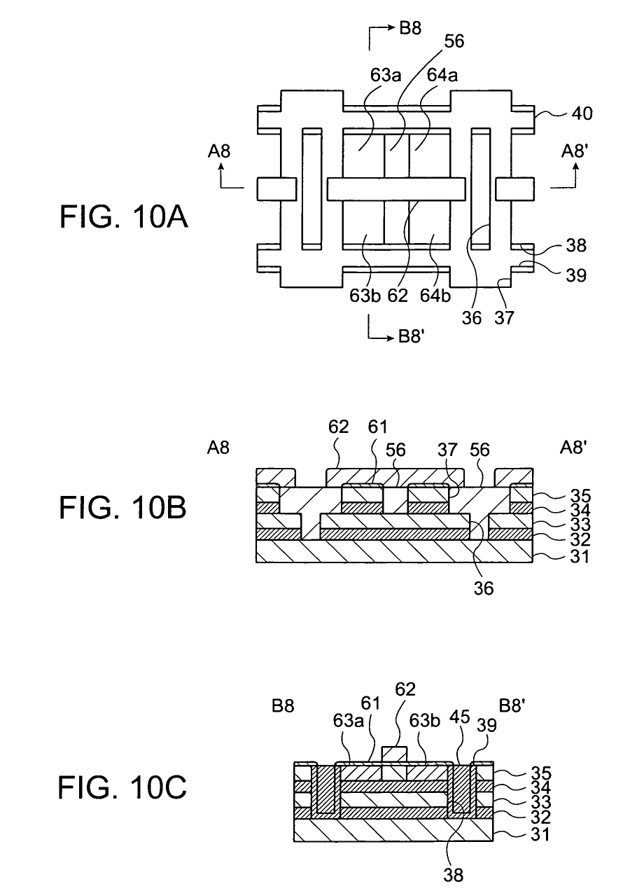

Referring next to FIGS. 10A to 10C, the surface of the single crystal semiconductor layer 35 is thermally oxidized to provide a gate insulating film 61 thereon. Then a polycrystalline silicon layer is provided by CVD, for example, on the semiconductor layer 35 provided with the gate insulating film 61. The polycrystalline silicon layer is patterned by photolithography and etching to provide a gate electrode 62 crossing the support member 56 and provided commonly to the single crystal semiconductor layers 35a and 35b.

Subsequently, impurity ions, such as B or BF₂, are implanted into the single crystal semiconductor layer 35a with the gate electrode 62 as a mask to provide a P-type source layer 63a and drain layer 63b sandwiching the gate electrode 62 to the semiconductor layer 35a. Meanwhile, impurity ions, such as As or P, are implanted into the single crystal semiconductor layer 35b with the gate electrode 62 as a mask to provide an N-type source layer 64a and drain layer 64b sandwiching the gate electrode 62 to the semiconductor layer 35b.

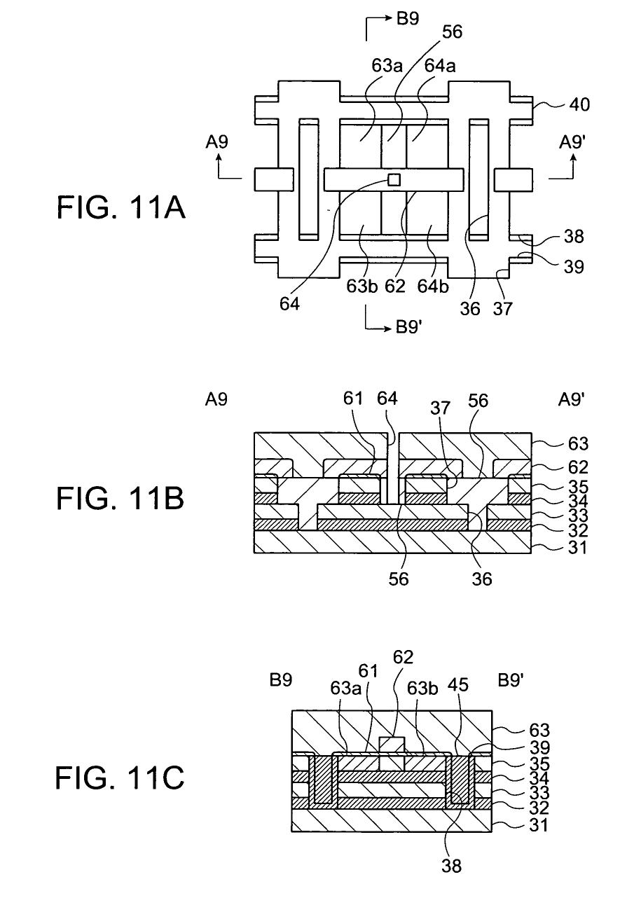

Referring next to FIGS. 11A to 11C, an insulating layer 63 is deposited on the gate electrode 62 by CVD, for example. Then the insulating layer 63, the gate electrode 62, the gate insulating film 61, the single crystal semiconductor layer 35, and the buried insulating layer 34 are patterned by photolithography and etching to form an opening 64 that penetrates the insulating layer 63, the gate electrode 62, the gate insulating film 61, the semiconductor layer 35, and the buried insulating layer 34 to expose the single crystal semiconductor layer 33.

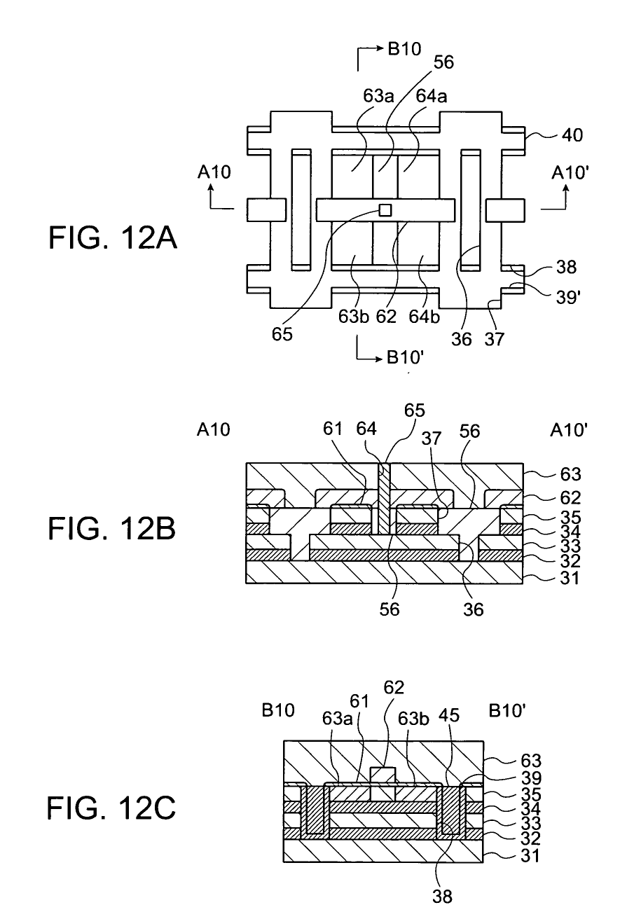

Referring next to FIGS. 12A to 12C, a conductive film is provided on the insulating layer 63 to fill the opening 64 by CVD, for example. The conductive film is patterned by photolithography and etching to form a buried electrode 65 that couples the gate electrode 62 and the single crystal semiconductor layer 33.

Accordingly, the P-channel and N-channel SOI transistors commonly having the gate electrode 62 can be provided to the single crystal semiconductor layer 35 without an SOI substrate. Here, the single crystal semiconductor layer 33 can function as a field plate. The field plate can be placed on the back surface of the semiconductor layer 35 provided with the SOI transistors. Even if the cavities 57a and 57b are formed under the semiconductor layers 33 and 35, the semiconductor layers 33 and 35 are supported on the semiconductor substrate 31 by providing the support member 56 buried in the trenches 36, 37, and 60, thereby providing a shallow trench isolation (STI) structure for isolating the semiconductor layer 35.

Consequently, this structure can increase control over potential of deep channel regions without restricting the layout of the gate electrode 62 and source/drain contact regions and isolate the P-channel and N-channel SOI transistors placed on the field plate while preventing a manufacturing process from becoming complicated. It is therefore possible to prevent manufacturing costs from increasing, reduce leakage current of a CMOS circuit during low-voltage driving and off, and increase the breakdown voltage of the CMOS circuit.

The entire disclosure of Japanese Patent Application Nos: 2005-200026, filed Jul. 8, 2005 and 2006-064595, filed Mar. 9, 2006 are expressly incorporated by reference herein.

What is claimed is:

1. A semiconductor device, comprising:
a semiconductor layer provided with a P-channel field-effect transistor and an N-channel field-effect transistor that have a common gate electrode;
a field plate provided to a back surface of the semiconductor layer with a first insulating layer therebetween and commonly for a channel of the P-channel field-effect transistor and a channel of the N-channel field-effect transistor; and
a second insulating layer placed under the field plate.

2. The semiconductor device according to claim 1, further comprising:
a wiring layer that couples the gate electrode and the field plate.

3. The semiconductor device according to claim 1, wherein the field plate has an area larger than active regions in the P-channel field-effect transistor and the N-channel field-effect transistor.

4. The semiconductor device according to claim 1, wherein the field plate is thicker than the semiconductor layer.

5. The semiconductor device according to claim 1, wherein the semiconductor layer and the field plate are made of one of a single crystal semiconductor material, a polycrystalline semiconductor material, and an amorphous semiconductor material.

6. The semiconductor device according to claim 1, wherein the first insulating layer is thicker than a gate insulating film included in the P-channel field-effect transistor and the N-channel field-effect transistor.

7. The semiconductor device according to claim 1, wherein the second insulating layer is thicker than the first insulating layer.

8. A semiconductor device, comprising:
a semiconductor layer to be mesa-isolated on a first insulating layer;
an isolation insulating layer buried between one region and another region of the mesa-isolated semiconductor layer;
a P-channel field-effect transistor and an N-channel field-effect transistor provided to the semiconductor layer so as to have a common gate electrode crossing the isolation insulating layer;
a field plate provided to a back surface of the semiconductor layer with the first insulating layer therebetween and commonly for a channel of the P-channel field-effect transistor and a channel of the N-channel field-effect transistor;
a second insulating layer placed under the field plate; and
a buried electrode penetrating the gate electrode, the isolation insulating layer, and the first insulating layer so as to be coupled to the semiconductor layer.

9. A method for manufacturing a semiconductor device, comprising:
providing a first semiconductor layer on a first insulating layer and providing a second semiconductor layer on the first semiconductor layer with a second insulating layer therebetween;
patterning the second semiconductor layer to mesa-isolate the second semiconductor layer into a first region and a second region;
burying an isolation insulating layer between one region and another region of the mesa-isolated second insulating layer;
providing a gate insulating film on a surface of the first region and a surface of the second region of the second semiconductor layer;
providing a gate electrode on the gate insulating film to cross the isolation insulating layer and cover the first region and the second region of the second semiconductor layer;
providing a first-conductivity-type source/drain layer in the first region of the second semiconductor layer;
providing a second-conductivity-type source/drain layer in the second region of the second semiconductor layer; and
providing a buried electrode penetrating the gate electrode, the isolation insulating layer, and the second insulating layer so as to be coupled to the first semiconductor layer.

10. A method for manufacturing a semiconductor device, comprising:
providing a plurality of multilayer structures on a semiconductor substrate, each multilayer structure including a first semiconductor layer and a second semiconductor layer whose etching rate is smaller than an etching rate of the first semiconductor layer on the first semiconductor layer;
providing a first trench penetrating the first semiconductor layer and the second semiconductor layer to expose the semiconductor substrate and providing a second trench penetrating an upper first semiconductor layer and an upper second semiconductor layer to expose a lower second semiconductor layer;
providing a support member buried in the first trench and the second trench to support the second semiconductor layer on the semiconductor substrate;
providing an exposing part to expose at least part of the first semiconductor layer from the second semiconductor layer;
selectively etching the first semiconductor layer through the exposing part to form a cavity from which the first semiconductor layer is removed;
providing a buried insulating layer buried in the cavity;
making the support member thin to provide an isolation insulating layer buried in the first trench;
providing a gate insulating film on a surface of the first region and a surface of the second region of the second semiconductor layer isolated by the first trench;
providing a gate electrode on the gate insulating film to cross the isolation insulating layer and cover the first region and the second region of the second semiconductor layer;
providing a first-conductivity-type source/drain layer in the first region of the second semiconductor layer; and
providing a second-conductivity-type source/drain layer in the second region of the second semiconductor layer.
